(19) United States
(12) Patent Application Publication
(10) Pub. No.: US 2026/0075730 A1
(43) Pub. Date: Mar. 12, 2026

(54) Latch for Enclosure

(71) Applicant: Robroy Enclosures, Inc., Belding, MI (US)

(72) Inventors: James William Hall, Clarksville, MI (US); Roger A. Schroder, Greenville, MI (US)

(21) Appl. No.: 19/326,823

(22) Filed: Sep. 12, 2025

Related U.S. Application Data
(60) Provisional application No. 63/693,932, filed on Sep. 12, 2024.

(51) Int. Cl. H05K 5/02

(52) U.S. Cl. CPC H05K 5/0221; H05K 5/0226

(57) ABSTRACT

A device for securing a door of an electrical enclosure includes a body, a bracket, and a hook member. The body includes flanges defining a bracket aperture and a hook aperture and wing tabs extending from the body at an angle with respect to the body. The bracket includes knuckles defining a knuckle aperture, and a lock flange extends from the bracket. The hook member includes projections defining a projection aperture and a hook portion extends from the hook member. A first hinge pin extends through the bracket aperture and the knuckle aperture to pivotally engage the body and the bracket and a second hinge pin extends through the hook aperture and the projection aperture to pivotally engage the body and the hook member. The wing tabs are configured to allow a user to grip the body to actuate the device from a closed position to an open position.

### CROSS-REFERENCE TO RELATED APPLICATION

This application claims the benefit of US Provisional Patent Application No. 63/693,932, which was filed September 12, 2024, the disclosure of which is hereby incorporated by reference in its entirety.

### BACKGROUND

### Field of the Disclosure

The present disclosure relates to a latch device and specifically to a latch device for securing a door of an electrical enclosure which allows for securely latching an electrical enclosure and facilitates easier and quicker access to the enclosure.

### Description of Related Art

Electrical enclosures are cabinets or containers for electrical or electronic components and equipment including circuits, circuit breakers, cables, wires, switches, knobs, displays, and the like used in industrial, residential, and commercial applications. Electrical enclosures are used to prevent electrical shock, fire, and other exposure to electricians, technicians or other users servicing equipment housed in electrical enclosures, as well as the surrounding environment or others who may come in contact with electrical enclosures. Electrical enclosures also protect the contents from the surrounding environment and weather conditions such as precipitation, wind, and sun exposure. Electrical enclosures are offered in a variety of shapes, sizes, dimensions, and materials such as metal, plastic, polymer, and composite materials. The shape, size, dimensions, and materials are selected based on the needs of a particular application. A multitude of governing bodies promulgate regulations requiring that electrical enclosures used in specific applications meet certain minimum requirements. For example, regulations may dictate the features and performance of electrical enclosures in hazardous areas, such as chemical plants or mineral mines, to protect the surrounding environment from heat dissipation, radio frequency interference or electrostatic discharge.

Over time, electrical enclosures and the components within may require repair, upgrade, installment, or other service. When required, electrical enclosures and components within are serviced in the field by electricians, technicians, or other users. Access to the components within an electrical enclosure is gained by opening a covering such as a hinged door or door panel, which may be mounted to the walls of an enclosure and securely held closed by a latch or similar fastener to add additional protection to users and the components within the electrical enclosure.

The door may be securely latched to the electrical enclosure to provide additional security and improved safety to both a user and the components within the enclosure by preventing accidental or unwanted opening of the enclosure. However, the security offered by door latch devices requires the latch to be actuated to an open or unlatched position to gain access inside of the enclosure. Actuating existing latches to an open position is often difficult due to the forces acting on the latch which secure the door in a closed position. Existing latches are awkward. uncomfortable. and non-ergonomic. which makes it more difficult for electricians, technicians, and other users servicing enclosures to open the latches. Additionally, users servicing enclosures in the field often wear personal protective equipment, including gloves, which make gripping and actuating door latch devices increasingly difficult. The factors often lead to users utilizing tools such as hammers, screwdrivers, and the like to apply large amounts of force to open the latch. This unintended use of tools and excessive force poses safety risks for users as well as damage risks to enclosure structures and the electrical components within. As there are often several latches securing the door, the difficult process of opening the latches can also be time consuming, and thus, there is an increase in cost associated with the time taken to open the latches for service or maintenance.

In view of the foregoing, there exists a need for a latch device for securing a door of an electrical enclosure, which allows for securely latching an electrical enclosure and facilitates easier and quicker access to the enclosure.

### SUMMARY

Accordingly, provided is a latch device for securing a door of an electrical enclosure which allows for securely latching an electrical enclosure, and facilitates easier and quicker access to the enclosure.

According to non-limiting embodiments or aspects of the disclosure, a device for securing a door of an electrical enclosure includes a body, a bracket, and a hook member. The body includes one or more flanges, a lock flange aperture, and one or more wing tabs extending from the body at an angle with respect to the body, the one or more flanges defining a bracket aperture and a hook aperture. The bracket includes one or more knuckles defining a knuckle aperture and a lock flange extending from the bracket. The hook member includes one or more projections defining a projection aperture and a hook portion extending from the hook member. A first hinge pin extends through the bracket aperture and the knuckle aperture to pivotally engage the body and the bracket and a second hinge pin extends through the hook aperture and the projection aperture to pivotally engage the body and the hook member. The one or more wing tabs are configured to allow a user to grip the body to actuate the device from a closed position to an open position.

According to other non-limiting embodiments or aspects of the disclosure, a device for securing a door of an electrical enclosure includes a body, a bracket, and a hook member. The body includes a first flange having a first bracket aperture and a first hook aperture, a second flange having a second bracket aperture concentric with the first bracket aperture and a second hook aperture concentric with the first hook aperture, a lock flange aperture, and two or more symmetric wing tabs extending from opposite sides of the body at an angle with respect to the body, which are configured to allow a user to grip the body to actuate the device. The bracket includes a first knuckle having a first knuckle aperture, a second knuckle having a second knuckle aperture concentric with the first knuckle aperture and a lock flange. The hook member includes a first projection having a first projection aperture a second projection having a second projection aperture concentric with the first projection aperture, and a hook portion. A first hinge pin extends through the first and second bracket apertures and the first and second knuckle apertures to pivotally engage the body and the bracket and a second hinge pin extends through the first and second hook apertures and the first and second projection apertures to pivotally engage the hook member and the body. The two or more symmetric wing tabs are configured to allow a user to grip the body to actuate the device.

Further non-limiting illustrative examples of embodiments of the present disclosure will now be set forth in the following numbered clauses.

Clause 1: A device for securing a door of an electrical enclosure, comprising: a body having one or more flanges, a lock flange aperture, and one or more wing tabs extending from the body at an angle with respect to the body, the one or more flanges defining a bracket aperture and a hook aperture; a bracket having one or more knuckles defining a knuckle aperture and a lock flange extending from the bracket; a hook member having one or more projections defining a projection aperture and a hook portion extending from the hook member a first hinge pin extending through the bracket aperture and the knuckle aperture to pivotally engage the body and the bracket; and a second hinge pin extends through the hook aperture and the projection aperture to pivotally engage the body and the hook member, wherein the one or more wing tabs are configured to allow a user to grip the body to actuate the device from a closed position to an open position.

Clause 2: The device according to clause 1 wherein the lock flange aperture engages the lock flange when the device is in a closed position.

Clause 3: The device according to clause 1 or 2, wherein the hook member is hooked toward the one or more knuckles and is configured to engage a catch portion on a door of an electrical enclosure.

Clause 4: The device according to any clauses 1-3, wherein the one or more wing tabs comprises two wing tabs extending from the opposite sides of the body.

Clause 5: The device according to any of clauses 1-4, wherein the two wing tabs are symmetric and the two wing tabs extend away from each other at an angle with respect to the body.

Clause 6: The device according to any of clauses 1-5, wherein the angle between each of the two wing tabs and the body is in the range inclusive of 100 degrees to 170 degrees.

Clause 7: The device according to any of clauses 1-6, wherein the angle between each of the two wing tabs and the body is 150 degrees.

Clause 8: The device according to any of clauses 1-7, wherein the one or more flanges comprises a first flange and a second flange, and wherein bracket aperture and the hook aperture extend through the first flange and the second flange.

Clause 9: The device according to any of clauses 1-8, wherein the first flange and the second flange extend perpendicularly from the body and parallel to each other.

Clause 10: The device according to any of clauses 1-9, wherein the first flange and the second flange are symmetric.

Clause 11: The device according to any of clauses 1-10, wherein the one or more wing tabs comprises two wing tabs extending from opposite sides of the body beyond the first flange and the second flange.

Clause 12: The device according to any of clauses 1-11, wherein the one or more knuckles comprises a first knuckle and a second knuckle, and wherein the knuckle aperture extends through the first knuckle and the second knuckle.

Clause 13: The device according to any of clauses 1-12, wherein the first knuckle and the second knuckle extend perpendicularly from the bracket and parallel to each other.

Clause 14: The device according to any of clauses 1-13, wherein the first knuckle and the second knuckle are symmetric.

Clause 15: The device according to any of clauses 1-14, wherein the lock flange extends perpendicularly from the bracket and comprises a lock aperture configured to receive a lock.

Clause 16: An electrical enclosure comprising: a door; one or more walls; one or more door hinges configured to pivotally connect the door to one of the one or more walls; and the device according to any of clauses 1-15 fastened to at least one of the one or more walls.

Clause 17: A device for securing a door of an electrical enclosure, comprising: a body comprised of: a first flange having a first bracket aperture and a first hook aperture; a second flange having a second bracket aperture concentric with the first bracket aperture and a second hook aperture concentric with the first hook aperture; a lock flange aperture; and two or more symmetric wing tabs extending from opposite sides of the body at an angle with respect to the body; a bracket comprised of a first knuckle having a first knuckle aperture; a second knuckle having a second knuckle aperture concentric with the first knuckle aperture; and a lock flange and a hook member comprised of a first projection having a first projection aperture a second projection having a second projection aperture concentric with the first projection aperture; and a hook portion, wherein a first hinge pin extends through the first and second bracket apertures and the first and second knuckle apertures to pivotally engage the body and the bracket, wherein a second hinge pin extends through the first and second hook apertures and the first and second projection apertures to pivotally engage the hook member and the body, and wherein the two or more symmetric wing tabs are configured to allow a user to grip the body to actuate the device.

Clause 18: The device according to clause 17, wherein the angle between each of the two or more symmetric wing tabs and the body is 150 degrees.

Clause 19: The device according to clause 17 or 18, wherein the lock flange extends from the bracket and comprises a lock aperture configured to receive a lock, wherein the lock flange aperture receives the lock flange when the device is in a closed position, and wherein the lock aperture is positioned such that when the lock flange is received by the lock flange aperture, the lock aperture extends through the lock flange aperture.

Clause 20: An electrical enclosure comprising a door one or more walls one or more door hinges configured to pivotally connect the door to one of the one or more walls; and the device according to any of clauses 17-19 fastened to at least one of the one or more walls, wherein a catch is positioned on the door of the electrical enclosure, and wherein the hook member is configured to engage with the catch to securely latch the door of the electrical enclosure.

Further details and advantages of the various examples described in detail herein will become clear upon reviewing the following detailed description of the various examples in conjunction with the accompanying drawing figures.

### BRIEF DESCRIPTION OF THE DRAWINGS

Additional advantages and details are explained in greater detail below with reference to the exemplary embodiments that are illustrated in the accompanying schematic figures, in which:

FIGS. 1A-1B are side views of a device for securing a door of an electrical enclosure according to some non-limiting embodiments or aspects of the present disclosure;

FIGS. 2A-2D are perspective plan side and sectional views of a body of the device of FIGS. 1A-1B according to some non-limiting embodiments or aspects of the present disclosure;

FIG. 2E is a plan view of a body of the device of FIGS. 1A-1B in a pre-bent state according to some non-limiting embodiments or aspects of the present disclosure;

FIGS. 3A-3B are perspective views of an implementation of the device of FIGS. 1A-1B according to some non-limiting embodiments or aspects of the present disclosure;

FIGS. 4A-4K are side views of the device of FIGS. 1A-1B in various states according to some non-limiting embodiments or aspects of the present disclosure; and

FIGS. 5A-5E are perspective views of an electrical enclosure including the device of FIGS. 1A-1B according to some non-limiting embodiments or aspects of the present disclosure.

Corresponding reference characters indicate corresponding parts throughout the several views. The exemplifications set out herein illustrate exemplary embodiments of the disclosure, and such embodiment are not to be construed as limiting the scope of the disclosure in any manner.

### DETAILED DESCRIPTION

It is to be understood that the present disclosure may assume various alternative variations and step sequences, except where expressly specified to the contrary. It is also to be understood that the specific devices and processes illustrated in the attached drawings, and described in the following specification, are simply exemplary and non-limiting embodiments or aspects. Hence, specific dimensions and other physical characteristics related to the embodiments or aspects disclosed herein are not to be considered as limiting.

For purposes of the description hereinafter, the terms "end," "upper," "lower," "right," "left," "vertical," "horizontal," "top," "bottom," "lateral," "longitudinal," and derivatives thereof shall relate to embodiments or aspects as they are oriented in the drawing figures. Some non-limiting embodiments or aspects may be described herein in connection with thresholds. As used herein, satisfying a threshold may refer to a value being greater than the threshold, more than the threshold, higher than the threshold, greater than or equal to the threshold, less than the threshold, fewer than the threshold, lower than the threshold, less than or equal to the threshold, equal to the threshold, etc.

No aspect, component, element, structure, act, step, function, instruction, and/or the like used herein should be construed as critical or essential unless explicitly described as such. Also, as used herein, the articles "a" and "an" are intended to include one or more items and may be used interchangeably with "one or more" and "at least one." Furthermore, as used herein, the term "set" is intended to include one or more items (e.g., related items, unrelated items, a combination of related and unrelated items, and/or the like) and may be used interchangeably with "one or more" or "at least one." Where only one item is intended, the term "one" or similar language is used. Also, as used herein, the terms "has," "have," "having," or the like are intended to be open-ended terms. Further, the phrase "based on" is intended to mean "based at least partially on" unless explicitly stated otherwise. In addition, reference to an action being "based on" a condition may refer to the action being "in response to" the condition.

Non-limiting embodiments or aspects of the present disclosure are generally directed to a latch device, and specifically to a latch device for securing a door of an electrical enclosure which allows for securely latching an electrical enclosure, and facilitates easier and quicker access to the enclosure.

According to non-limiting embodiments, the device may include a body, a bracket, and a hook member. The body may include one or more flanges, a lock flange aperture, and one or more wing tabs extending from the body at an angle with respect to the body, the one or more flanges defining a bracket aperture and a hook aperture. The bracket may include one or more knuckles defining a knuckle aperture and a lock flange extending from the bracket. The hook member may include one or more projections defining a projection aperture and a hook portion extending from the hook member. The device may further include a first hinge pin extending through the bracket aperture and the knuckle aperture to pivotally engage the body and the bracket, and a second hinge pin extends through the hook aperture and the projection aperture to pivotally engage the body and the hook member. The one or more wing tabs are configured to allow a user to grip the body to actuate the device from a closed position to an open position.

In this way, embodiments of the present disclosure provide a latch device for securing a door of an electrical enclosure, which allows for securely latching an electrical enclosure and facilitates easier and quicker access to the enclosure.

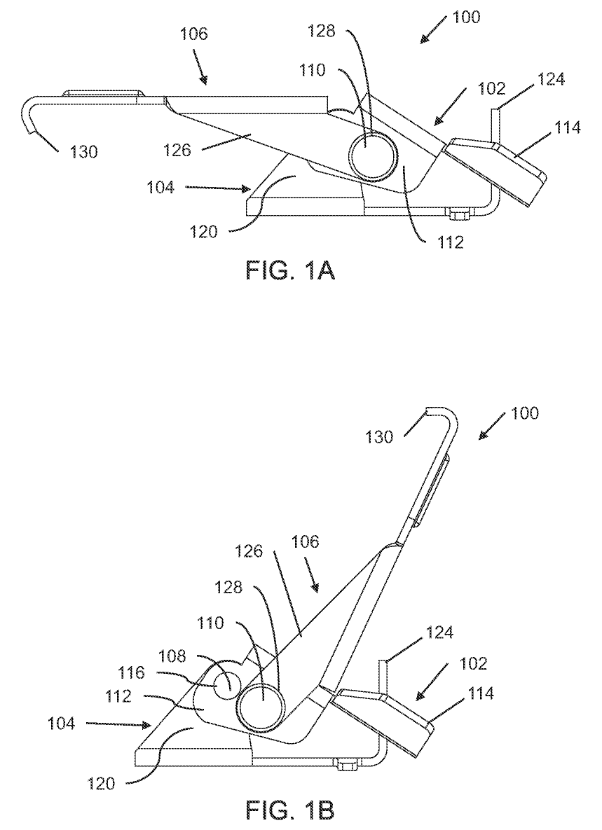

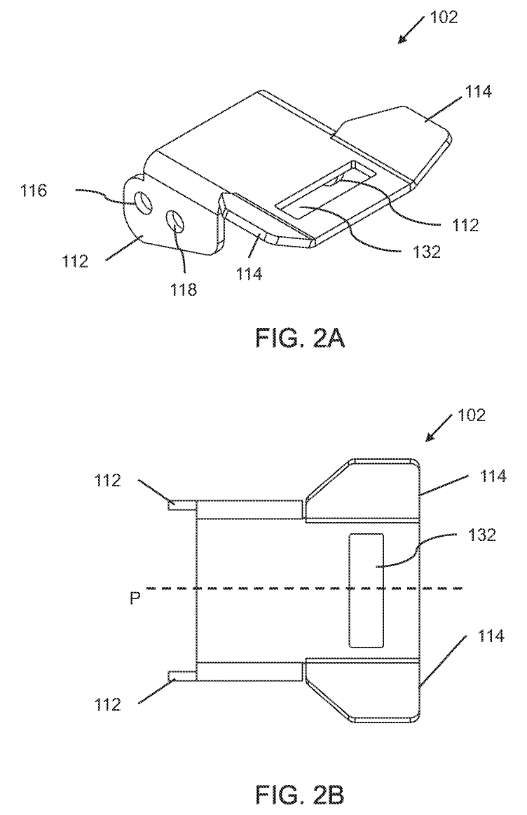

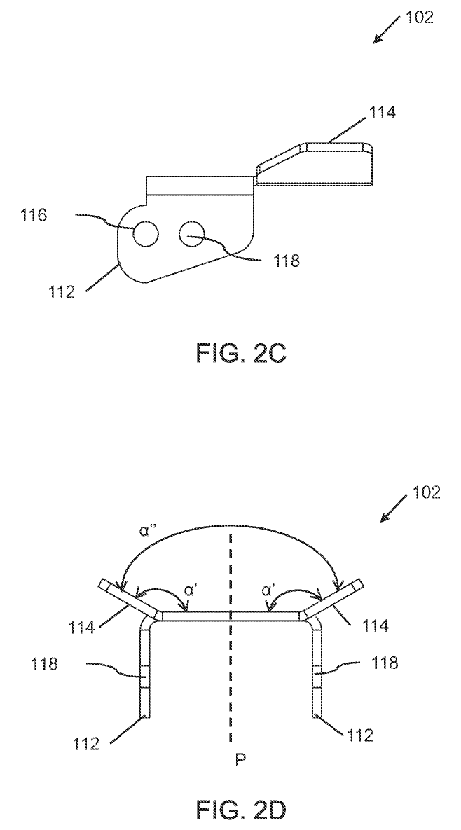

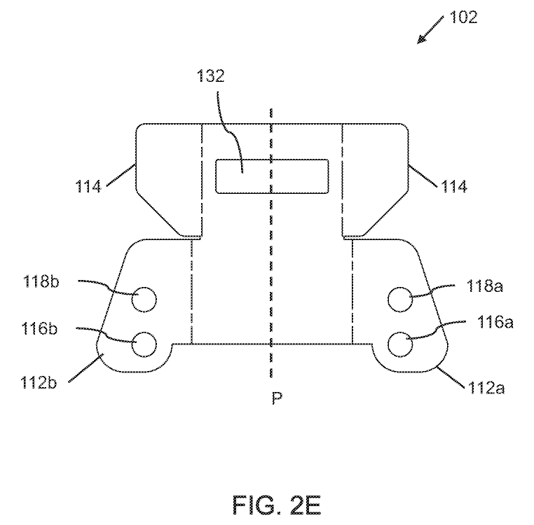

Referring now to FIGS. 1A-1B, FIGS. 1A -1B are side views of device 100 for securing a door of an electrical enclosure according to some non-limiting embodiments or aspects of the present disclosure. As shown in FIG. 1A, device 100 may include body 102, bracket 104, hook member 106, first hinge pin 108 and second hinge pin 110. In some non-limiting embodiments, body 102 may have one or more flanges 112 and one or more wing tabs 114. In some non-limiting embodiments, one or more wing tabs 114 may extend from body 102 at an angle with respect to body 102 (e.g., angle a' shown in FIG. 2D). One or more wing tabs 114 may be configured to allow a user to grip the body to actuate the device from a closed position to an open position.

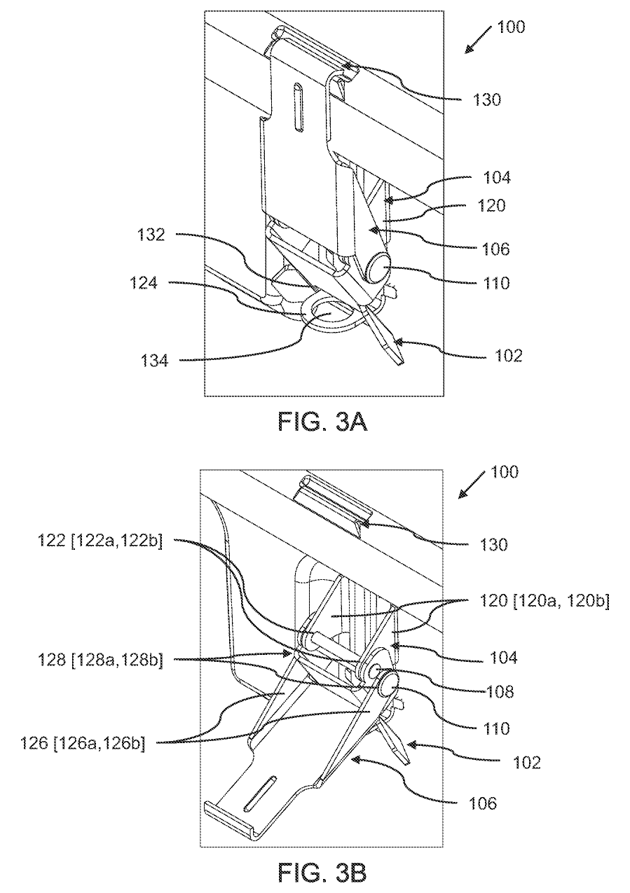

In some non-limiting embodiments, one or more flanges 112 may define bracket aperture 116 and a hook aperture (e.g., hook aperture 118 shown in FIGS. 2A and 2C). In some non-limiting embodiments, bracket 104 may include one or more knuckles 120 and one or more knuckles 120 may define a knuckle aperture (e.g., knuckle apertures 122 shown in FIG. 3B). In some non-limiting embodiments, bracket 104 may include lock flange 124 extending from bracket 104. In some non-limiting embodiments, lock flange 124 may extend perpendicularly from bracket 104 and may include a lock aperture (e.g., lock aperture 134 shown in FIG. 3A) configured to receive a lock. In some non-limiting embodiments, hook member 106 may have one or more projections 126, and one or more projections 126 may define projection aperture 128. In some non-limiting embodiments, hook member 106 may define hook portion 130 extending from hook member 106. Hook member 106 may be configured to engage a catch portion of a door of an electrical enclosure with hook portion 130. In some non-limiting embodiments, hook member 106 with hook portion 130 may be hooked toward one or more knuckles 120.

In the exemplary embodiments, FIG. 1A depicts device 100 in a closed or latched state and FIG. 1B depicts device 100 in an open or unlatched state. In some non-limiting embodiments, first hinge pin 108 may extend through bracket aperture 116 of body 102 and a knuckle aperture 122 of bracket 104 (shown in FIG. 3B) to pivotally engage body 102 and bracket 104. In some non-limiting embodiments, second hinge pin 110 may extend through hook aperture 118 of body 102 (shown in FIGS. 2A and 2C) and projection aperture 128 of hook member 106. In some non- limiting embodiments, first hinge pin 108 may include a central axis and may define a first axis of rotation about which body 102 rotates with respect to bracket 104. Similarly, in some non-limiting embodiments, second hinge pin 110 may include a central axis and may define a second axis of rotation about which hook member 106 rotates with respect to body 102.

Referring now to FIGS. 2A-2E, FIGS. 2A-2D are perspective, plan, side, and sectional views of body 102 of device 100 according to some non-limiting embodiments or aspects of the present disclosure, and FIG. 2E is a plan view of body 102 in a pre-bent state. In some non-limiting embodiments, device 100 including body 102, bracket 104, and hook member 106 may be symmetric across a center plane P, shown with respect to body 102 in FIGS. 2B, 2D, and 2E.

Accordingly, in some non-limiting embodiments, shown for example in the pre-bent plan view of FIG. 2E, one or more flanges 112 may include first flange 112a and second flange 112b, and bracket aperture 116 and hook aperture 118 may extend through first flange 112a and second flange 112b. Thus, first flange 112a may define first bracket aperture 116a and first hook aperture 118a, and second flange 112b may define second bracket aperture 116b and second hook aperture 118b, such that first bracket aperture 116a and second bracket aperture 116b are concentric and first hook aperture 118a and second hook aperture 118b are concentric. In some non-limiting embodiments, as shown in FIGS. 2A-2D, first flange 112a and second flange 112b may extend perpendicularly from the body and parallel to each other.

Similarly, and with continued reference to FIGS. 2A-2E, in some non-limiting embodiments, one or more wing tabs 114 may be two wing tabs 114 extending from opposite sides of body 102. In some non-limiting embodiments, as shown in FIG. 2D, two wing tabs 114 may be symmetric and may extend away from each other from opposite sides of body 102 beyond first flange 112a and second flange 112b. In some non-limiting embodiments, two wing tabs 114 may extend from body 102 at angle a' with respect to body 102. Accordingly, two wing tabs 114 may also extend away from each other at an angle a" with respect to each other. In some non-limiting embodiments, angle a' between each of the two wing tabs and the body may be in the range inclusive of 100 degrees to 170 degrees, and preferably, may be 150 degrees Thus, a" between respective wing tabs may be in the range inclusive of 20 degrees to 160 degrees, and preferably, may be 120 degrees. In this configuration, wing tabs 114 sufficiently and optimally allow a user to grip body 102 to actuate device 100 from the closed position to the open position while minimizing the footprint and risk of snags and other risks. Two wing tabs 114 may obviate the need for a user to use a tool such as a hammer or screw driver and/or excessive force to latch (close) and/or unlatch (open) device 100 and thus, an electrical enclosure, thereby improving user safety and reducing the risk of harm to a user and damage to the enclosure and/or its components.

With reference to FIGS. 2A, 2B, and 2E, in some non-limiting embodiments, body 102 may include lock flange aperture 132 and lock flange aperture 132 may be configured to receive lock flange 124. In some non-limiting embodiments, lock flange aperture 132 may be configured to engage lock flange 124 when device 100 is in the closed position. For example, lock flange aperture 132 may engage lock flange 124 by slip fit or friction fit to provide additional security to device 100 and to ensure alignment of device 100 is maintained in the close position.

Referring now to FIGS. 3A-3B, FIGS. 3A-3B are perspective views of an implementation of device 100 according to some non-limiting embodiments or aspects of the present disclosure. As shown in FIGS. 3A-3B, bracket 104 may also be symmetric such that one or more knuckles 120 include first knuckle 120a and second knuckle 120b. Thus, knuckle aperture 122 may extend through first knuckle 120a and second knuckle 120b such that first knuckle 120a defines first knuckle aperture 122a and second knuckle 120b defines second knuckle aperture 122b. In some non-limiting embodiments, first knuckle aperture 122a may be concentric with the second knuckle aperture 122b. In some non-limiting embodiments, first knuckle 120a and second knuckle 120b may extend perpendicularly from bracket 104 and parallel to each other.

Similarly, with continued reference to FIGS. 3A-3B, hook member 106 may also be symmetric such that one or more projections 126 include first projection 126a and second projection 126b. Thus, projection aperture 128 may extend through first projection 126a and second projection 126b such that first projection 126a defines first projection aperture 128a and second projection 126b defines second projection aperture 128b. In some non-limiting embodiments, first projection aperture 128a and second projection aperture 128b may be concentric. In some non-limiting embodiments, first projection 126a and second projection 126b may extend perpendicularly from hook member 106 and parallel to each other.

Accordingly, in some non-limiting embodiments, first hinge pin 108 may extend through the first bracket aperture 116a, first knuckle aperture 122a, second knuckle aperture 122b, and second bracket aperture 116b to pivotally engage body 102 and bracket 104. Second hinge pin 110 may extend through the first projection aperture 128a, first hook aperture 118a, second hook aperture 118b, and second projection aperture 128b, and to pivotally engage hook member 106 and the 102.

However, it is also contemplated that that device 100 including body 102, bracket 104, and hook member 106 may not be symmetric and device 100 may include one or any number of wing tabs 114, flanges 112, knuckles 120, and/or projections 126.

In some non-limiting embodiments, as shown in FIG. 3A, In some non- limiting embodiments, lock flange 124 may extend perpendicularly from bracket 104 and may include lock aperture 134 and lock aperture 134 may be configured to receive a lock. In some non-limiting embodiments, lock flange aperture 132 may receive lock flange 124 when device 100 is in a closed position, as shown in FIG. 3A. In some non-limiting embodiments, lock aperture 134 may be positioned such that when lock flange 124 is received by lock flange aperture, lock aperture 134 may extend through lock flange aperture 132. In this way, a lock may be inserted into lock aperture 134 to lock device 100 in a closed position. Conversely, a lock may be inserted into lock aperture 134 where lock aperture 134 is not extending through lock flange aperture 132 to prevent device 100 from latching.

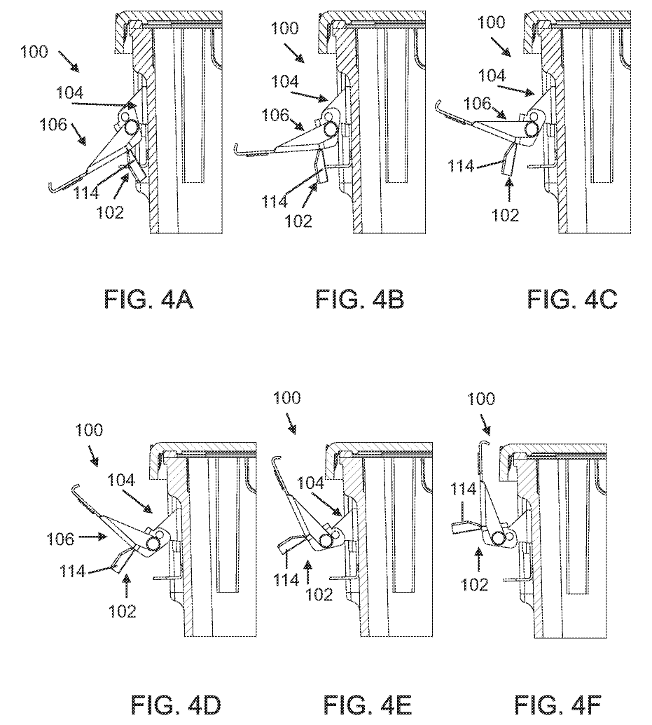

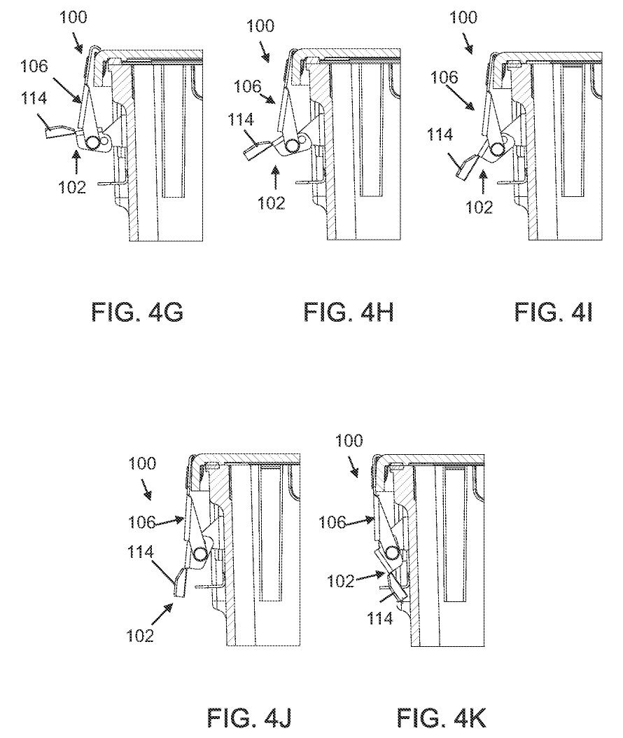

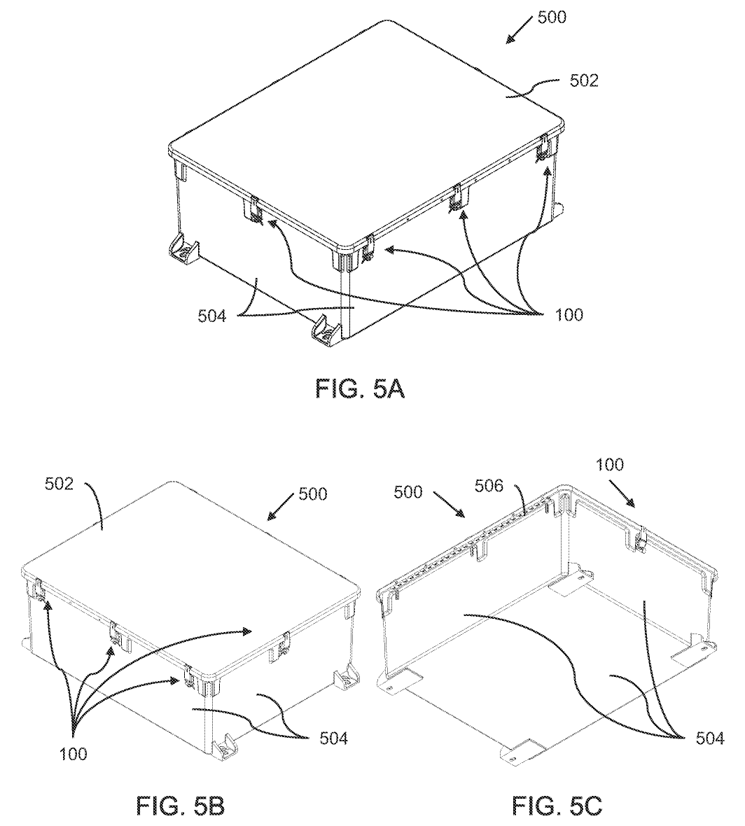

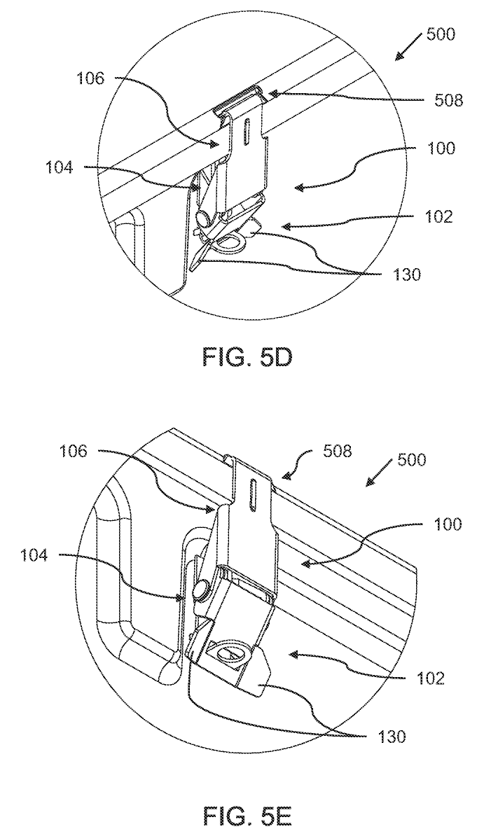

Referring now to FIGS. 4A-4K, FIGS. 4A-4K are side views of device 100 in various states according to some non-limiting embodiments or aspects of the present disclosure. FIG. 4A depicts a fully unlatched (open) state or position of device 100. FIGS. 4B-4J depict progressive states of latching (closing) device 100. FIG. 4K depicts a fully latched (closed) state or position of device 100. In some non-limiting embodiments, as shown in FIGS. 3A-3B and 4A-4K, bracket 104 of device 100 may be fastened to a wall of an electrical enclosure (e.g., electrical enclosure 500 as shown in FIGS. 5A-5E). In some non-limiting embodiments of device 100, a catch of electrical enclosure may be positioned on a door of the electrical enclosure, and hook member 106 may be configured to engage with the catch to securely latch the door of the electrical enclosure. In some non-limiting embodiments, as shown in FIGS. 4A-46, the hinge pins (e.g., firs hinge pin 108 and second hinge pin 110 shown in FIGS. 1A-1B) may define axes of rotation about which body 102 rotates with respect to bracket 104 and about which hook member 106 rotates with respect to body 102 to allow hook member 106 to engage with the catch of the electrical enclosure and to allow body 102(e.g., lock flange aperture 132) to engage with bracket 104 (i.e., lock flange 124) to hold and secure device 100, and thus, the associated electrical enclosure, in a closed and locked position.

Referring now to FIGS. 5A-5E, 5A-5E are perspective views of electrical enclosure 500 according to some non-limiting embodiments or aspects of the present disclosure. As shown in FIGS. 5A-5E, electrical enclosure 500 may include door 502, one or more walls 504, one or more door hinges 506 configured to pivotally connect the door to one of the one or more walls 504, and one or more devices 100 may be fastened to at least one of the one or more walls. In some non-limiting embodiments as described herein, each of the one or more devices 100 may include body 102, bracket 104, hook member 106, and body 102 may include a first flange having a first bracket aperture and a first hook aperture, a second flange having a second bracket aperture concentric with the first bracket aperture and a second hook aperture concentric with the first hook aperture, a lock flange aperture, and two or more symmetric wing tabs 114 extending from opposite sides of body 102 at an angle with respect to body 102. Electrical enclosure 500 may further include catch portion 508 positioned on the door for receiving hook member 106 of device 100. As further shown in FIGS. 5A-5E, electrical enclosure 500 may include multiple devices 100 for securing a door of the electrical enclosure.

It is to be understood that while the embodiments of the present disclosure have been described with respect to a device for securing a door of an electrical enclosure, the devices and assemblies are applicable for, but not limited to, implementation with regard to securing any number of doors, panels and or any number of other components to or in an electrical enclosure and/or any other conceivable enclosure or door, and it is considered that there are various other configurations and uses for securing and fixing various elements with the devices and assemblies of the present disclosure.

While several examples, of device for securing a door of an electrical enclosure are shown in the accompanying figures and described in detail hereinabove, other aspects will be apparent to, and readily made by, those skilled in the art without departing from the scope and spirit of the disclosure. Accordingly, the foregoing description is intended to be illustrative rather than restrictive. The disclosure described hereinabove is defined by the appended claims and all changes to the disclosure that fall within the meaning and range of equivalency of the claims are to be embraced within their scope.

What is claimed is:

1. A device for securing a door of an electrical enclosure, comprising:
a body having one or more flanges, a lock flange aperture, and one or more wing tabs extending from the body at an angle with respect to the body, the one or more flanges defining a bracket aperture and a hook aperture;
a bracket having one or more knuckles defining a knuckle aperture and a lock flange extending from the bracket;
a hook member having one or more projections defining a projection aperture and a hook portion extending from the hook member;
a first hinge pin extending through the bracket aperture and the knuckle aperture to pivotally engage the body and the bracket; and
a second hinge pin extends through the hook aperture and the projection aperture to pivotally engage the body and the hook member,
wherein the one or more wing tabs are configured to allow a user to grip the body to actuate the device from a closed position to an open position.

2. The device according to claim 1, wherein the lock flange aperture engages the lock flange when the device is in a closed position.

3. The device according to claim 1, wherein the hook member is hooked toward the one or more knuckles and is configured to engage a catch portion on a door of an electrical enclosure.

4. The device according to claim 1, wherein the one or more wing tabs comprises two wing tabs extending from opposite sides of the body.

5. The device according to claim 3, wherein the two wing tabs are symmetric and the two wing tabs extend away from each other at an angle with respect to the body.

6. The device according to claim 5, wherein the angle between each of the two wing tabs and the body is in the range inclusive of 100 degrees to 170 degrees.

7. The device according to claim 6, wherein the angle between each of the two wing tabs and the body is 150 degrees.

8. The device according to claim 1,
wherein the one or more flanges comprises a first flange and a second flange, and
wherein bracket aperture and the hook aperture extend through the first flange and the second flange.

9. The device according to claim 8, wherein the first flange and the second flange extend perpendicularly from the body and parallel to each other.

10. The device according to claim 9, wherein the first flange and the second flange are symmetric.

11. The device according to claim 8, wherein the one or more wing tabs comprises two wing tabs extending from opposite sides of the body beyond the first flange and the second flange.

12. The device according to claim 1,
wherein the one or more knuckles comprises a first knuckle and a second knuckle, and
wherein the knuckle aperture extends through the first knuckle and the second knuckle.

13. The device according to claim 12, wherein the first knuckle and the second knuckle extend perpendicularly from the bracket and parallel to each other.

14. The device according to claim 13, wherein the first knuckle and the second knuckle are symmetric.

15. The device according to claim 11, wherein the lock flange extends perpendicularly from the bracket and comprises a lock aperture configured to receive a lock.

16. An electrical enclosure comprising:
a door;
one or more walls;
one or more door hinges configured to pivotally connect the door to one of the one or more walls; and
the device according to claim 1 fastened to at least one of the one or more walls.

17. A device for securing a door of an electrical enclosure, comprising:
a body comprised of:
a first flange having a first bracket aperture and a first hook aperture;
a second flange having a second bracket aperture concentric with the first bracket aperture and a second hook aperture concentric with the first hook aperture;
a lock flange aperture; and
two or more symmetric wing tabs extending from opposite sides of the body at an angle with respect to the body;
a bracket comprised of:
a first knuckle having a first knuckle aperture;
a second knuckle having a second knuckle aperture concentric with the first knuckle aperture; and
a lock flange; and
a hook member comprised of:
a first projection having a first projection aperture;
a second projection having a second projection aperture concentric with the first projection aperture; and
a hook portion,
wherein a first hinge pin extends through the first and second bracket apertures and the first and second knuckle apertures to pivotally engage the body and the bracket,
wherein a second hinge pin extends through the first and second hook apertures and the first and second projection apertures to pivotally engage the hook member and the body, and
wherein the two or more symmetric wing tabs are configured to allow a user to grip the body to actuate the device.

18. The device according to claim 17, wherein the angle between each of the two or more symmetric wing tabs and the body is 150 degrees.

19. The device according to claim 17,
wherein the lock flange extends from the bracket and comprises a lock aperture configured to receive a lock,
wherein the lock flange aperture receives the lock flange when the device is in a closed position, and
wherein the lock aperture is positioned such that when the lock flange is received by the lock flange aperture, the lock aperture extends through the lock flange aperture.

20. An electrical enclosure comprising:
a door;
one or more walls;
one or more door hinges configured to pivotally connect the door to one of the one or more walls; and
the device according to claim 17 fastened to at least one of the one or more walls,
wherein a catch is positioned on the door of the electrical enclosure, and
wherein the hook member is configured to engage with the catch to securely latch the door of the electrical enclosure.
